(19) United States
(12) Patent Application Publication
(10) Pub. No.: US 2024/0240311 A1
(43) Pub. Date: Jul. 18, 2024

(54) SCALABLE METHOD FOR ACHIEVING SHAPE CONTROL OF DIAMOND MICRO-NANOPARTICLES

(71) Applicants: Versitech Limited, Hong Kong (CN); Southern University of Science and Technology, Shenzhen (CN); Dongguan Institute of Opto-electronics, Peking University, Dongguan (CN)

(72) Inventors: Zhiqin CHU, Hong Kong (CN); Tongtong ZHANG, Hong Kong (CN); Qi WANG, Dongguan (CN); Zhongqiang WANG, Dongguan (CN); Kwai Hei LI, Shenzhen (CN)

(73) Assignees: Versitech Limited, Hong Kong (CN); Southern University of Science and Technology, Shenzhen (CN); Dongguan Institute of Opto-electronics, Peking University, Dongguan (CN)

(21) Appl. No.: 18/416,325

(22) Filed: Jan. 18, 2024

(30) Foreign Application Priority Data
Jan. 18, 2023 (CN) 202310062039.5

(51) Int. Cl. C23C 16/44; C23C 16/02; C23C 16/27; C23C 16/511; C23C 16/56

(52) U.S. Cl. CPC C23C 16/4417; C23C 16/0227; C23C 16/274; C23C 16/511; C23C 16/56

(57) ABSTRACT

The present invention provides a scalable method for achieving shape control of diamond micro-nanoparticles, comprising air oxidizing diamond micro-nanoparticles grown by chemical vapor deposition and/or diamond micro-nanoparticles grown by high pressure and high temperature. The present invention achieves the controllable morphology transformation of diamond micro-nanoparticles via air oxidation treatment. It has been demonstrated that a series of unique shapes, including “flower” shaped, “hollow” structured, “pyramid” patterned on the surface, and “boomerang” shaped, can be achieved by altering the air oxidation parameters, i.e., temperature and duration. The scalable production of these differently shaped diamond micro-nanoparticles represents a significant scientific breakthrough together with a high commercial value. The ability to produce diamond particles with desired shapes simply and cost-effectively will remove many obstacles to using diamonds for practical applications in nanophotonics, quantum computing, quantum optics, etc.

### CROSS-REFERENCE TO RELATED PATENT APPLICATION

This application claims the benefit of priority to Chinese Patent Applications No. 202310062039.5 filed on 18 Jan. 2023, the contents of which are incorporated herein by reference in its entirety.

### TECHNICAL FIELD

The present invention belongs to the technical field of nanomaterial. Specifically, the present invention relates to a scalable method for achieving shape control of diamond micro-nanoparticles.

### BACKGROUND ART

The geometric feature of microparticles and nanoparticles (micro-and nanoparticles or micro-nanoparticles) is one of the most significant parameters for endowing their functions, and thus many efforts have been devoted to realizing the shape control thereof. Achieving a variable shape of micro-nanoparticles is an interesting challenge that requires bringing together a variety of disparate concepts from a multitude of diverse disciplines. Moreover, materials with unique and complex nanostructured order possess many functional properties, including targeting abilities and optical tunability, and the expansions (large-scale) of the structures available upon design will create even further functional materials with a range of special proprieties. Therefore, effectively tailoring micro-nanoparticles into the desired shape is key to realizing their particular performance.

The diamond material has demonstrated a wide range of potential applications from basic science to industrial fields due to its outstanding optical and spectroscopic properties, high thermal conductivity, high mechanical strength, excellent biocompatibility, and flexible surface properties, etc . . . With the rapid development of synthesis and engineering methods, the diamond material can be fabricated into different structures according to specific applications. For example, the bulk diamond has been fabricated into several photonic structures, such as nanowires, and nanopillars, using well-developed nanofabrication techniques. At the same time, the diamond micro-nanoparticles, have gained worldwide attention because of their tunable size (down to a few nanometers for stably hosting color centers), excellent biocompatibility, and fruitful surface chemistry.

The advanced nanofabrication techniques might be able to tune the shape of individual diamond micro-nanoparticle. However, there are no available feasible techniques for the scalable engineering of their shapes (e.g., from the typical “polyhedron” to shapes with complex nanostructures) due to their high hardness, small particle size, irregular shape, chemical inertness, and high cost. Researchers have realized the importance of shape control of diamond micro-nanoparticles, e.g., the proposed shape-dependent optical measurements. Unfortunately, the exploration of shape engineering-based applications is quite limited due to the lack of technical methods. Therefore, developing new techniques and processes for the shape engineering of diamond materials, especially the diamond micro-nanoparticles, is critical for the successful realization of their potential applications in nanomechanics, optomechanics, nanophotonics, quantum computing, quantum optics, etc.

CN111099586A discloses a method for the preparation of high-brightness SiV nanodiamonds, which introduces SiV by using tetramethylsilane gas as the silicon source during CVD growth. The most important aspect is that it uses short air annealing time (5-10 min) to treat the diamonds, which converts the surface chemical functional groups from hydrogenated to oxidized, thereby improving the brightness of SiV. However, the method does not achieve a change in the shape of the diamond, nor is it intended to do so.

CN115181957A discloses a method of preparing diamond micro-nanopowders or composites in which the diamond layers can be adjusted to meet structural, performance and purity requirements through a stepwise multiple growth method. Therefore, the method adjusts the parameters during the “bottom-up” diamond growth process to change the properties of the prepared diamond material.

### SUMMARY OF THE INVENTION

It is an object of the present invention to develop a scalable method for achieving shape control of diamond micro-nanoparticles.

As used herein, the term “scalable” refers to the ability of the method to simultaneously produce multiple (or large numbers) of diamond micro-nanoparticles with the desired shape. In contrast, existing nanofabrication techniques can only control or tune the shape of individual diamond micro-nanoparticle.

As used herein, the term “micro-nanoparticles” refers to particles in the micrometer or nanometer range. For example, the particle size of the said micro-nanoparticles may be 10 nm to 10 μm, preferably 100 nm to 2 μm.

In a first aspect, the present invention provides a scalable method for achieving shape control of diamond micro-nanoparticles, comprising air oxidizing diamond micro-nanoparticles grown by chemical vapor deposition and/or the diamond micro-nanoparticles grown by high pressure and high temperature, wherein,
diamond micro-nanoparticles with a mean particle size of 10 nm to 500 nm are subjected to air oxidation under one of the following conditions:
5-25 hours of oxidation in the air at 530-570° C.;
10 min-10 hours of oxidation in the air at 580-620° C.; and diamond micro-nanoparticles with a mean particle size of greater than 500 nm to 10 μm are subjected to air oxidation under one of the following conditions:
10-35 hours of oxidation in the air at 580-620° C.;
5-25 hours of oxidation in the air at 630-670° C.

The method according to the present invention is directed to diamond micro-nanoparticles grown by high pressure and high temperature (HPHT) which may be commercially available diamond micro-nanoparticles with an average particle size in the range of 10 nm to 10 μm, preferably 100 nm to 2 μm; and to diamond micro-nanoparticles grown by chemical vapor deposition which may be diamond micro-nanoparticles prepared with commercially available diamond micro-nanoparticles grown by high pressure and high temperature as raw materials by chemical vapor deposition (CVD), typically with an average particle size of 500 nm to 10 μm, preferably 1 to 2 μm.

In some embodiments of the present invention, the preparation method for the diamond micro-nanoparticles grown by chemical vapor deposition comprises the following steps:
(1) mixing the diamond micro-nanoparticles grown by high pressure and high temperature with sodium chloride, and heating at 400-600° C. for 0.5-2 hours in the air; and dispersing the resultant product in deionized water and sonicating it, purifying it with deionized water one to five times by centrifugation, then re-dispersing it in deionized water and sonicating it for 0.5-3 hours to obtain a suspension of the diamond micro-nanoparticles; and
(2) spin-coating the suspension obtained in step (1) on a hydrogen plasma treated standard single-crystal Si substrate, and then putting the suspension spin-coated Si substrate in a microwave-plasma assisted chemical vapor deposition system with a gas mixture of H₂ and methane for the growth of the diamond micro-nanoparticles.

In the preparation method according to the present invention, the diamond micro-nanoparticles grown by high pressure and high temperature in step (1) preferably have a mean particle size of 50 nm to 200 nm.

Preferably, the diamond micro-nanoparticles grown in step (2) have a mean particle size of 1 to 2 μm.

In a second aspect, the present invention provides a scalable method for preparing diamond microparticles with a flower like shape, comprising air oxidizing diamond micro-nanoparticles having a mean particle size of 1 to 2 μm grown by chemical vapor deposition in the air at 580-620° C. for 25-35 hours.

In a third aspect, the present invention provides a scalable method for preparing diamond microparticles with “pyramid” patterns on the surface, comprising air oxidizing diamond micro-nanoparticles having a mean particle size of 1 to 2 μm grown by chemical vapor deposition in the air at 580-620° C. for 10-20 hours.

In a fourth aspect, the present invention provides a scalable method for preparing diamond microparticles with hollow structures, comprising air oxidizing diamond micro-nanoparticles having a mean particle size of 1 to 2 μm grown by chemical vapor deposition in the air at 630-670° C. for 15-25 hours.

In a fifth aspect, the present invention provides a scalable method for preparing diamond nanoparticles with “pyramid” patterns on the surface, comprising air oxidizing diamond micro-nanoparticles having a mean particle size of 100 to 500 nm grown by high pressure and high temperature under one of the following conditions:
5-25 hours of oxidation in the air at 530-570° C.;
30 min-5 hours of oxidation in the air at 580-620° C.

In a sixth aspect, the present invention provides a scalable method for preparing diamond microparticles with a boomerang like shape, comprising air oxidizing diamond micro-nanoparticles having a mean particle size of 500 nm to 2 μm grown by high pressure and high temperature in the air at 580-620° C. for 10-30 hours.

The present invention achieves controllable morphology transformation of diamond micro-nanoparticles via air oxidation treatment. It has been demonstrated that a series of unique shapes, including “flower” shaped, “hollow” structured, “pyramid” patterned on the surface, and “boomerang” shaped, can be achieved by altering the air oxidation parameters, i.e., temperature and duration. The scalable production of these differently shaped diamond micro-nanoparticles represents a significant scientific breakthrough together with a high commercial value. The ability to produce diamond particles with desired shapes simply and cost-effectively will remove many obstacles to using diamonds for practical applications in nanophotonics, quantum computing, quantum optics, etc.

Compared to the method of CN111099586A, the present invention focuses on controlling the shape of the diamond by using a much longer oxidation time (mostly several hours). In addition, the diamond used in the present invention is not limited to CVD growth, and the shape control of HPHT-grown diamonds can also be achieved through the method proposed by the present invention. At the same time, the present invention does not emphasize the impact of oxidation on internal color centers (e.g., SiV, NV).

Compared to the method described in CN115181957A, the present invention differs in that it reshapes the diamonds fabricated through various methods (such as CVD and HPHT) in a “top-down” manner, specifically through high-temperature oxidation to change the shape of the diamond.

### BRIEF DESCRIPTION OF THE DRAWINGS

Hereinafter, embodiments of the present invention are described in detail in conjunction with the accompanying drawings, wherein:

FIG. 1 shows (a) the scanning electron microscopy (SEM) images, (b) the Raman spectrum, and (c) the X-ray diffraction (XRD) result of the CVD diamond microparticles prepared in Example 1 of the present invention.

FIG. 2 shows (a) the SEM images, (b) the Raman spectrum, and (c) the XRD result of the flower shaped CVD diamond microparticles prepared in Example 2 of the present invention.

FIG. 3 shows the SEM images of the CVD diamond microparticles with “pyramid” patterns on the surface prepared in Example 3 of the present invention.

FIG. 4 shows the SEM images of the CVD diamond microparticles with “hollow” structures prepared in Example 4 of the present invention.

FIG. 5 shows the SEM images of (a) the CVD-grown diamond microparticles and (b) densely packed “hollow” structured CVD diamond microparticles after air oxidation prepared in Example 5.

FIG. 6 shows the SEM and transmission electron microscope (TEM) images of the starting material HPHT diamond nanoparticles and the HPHT diamond nanoparticles treated by four treating modes in Example 6.

FIG. 7 shows the TEM images of the starting material HPHT diamond nanoparticles and the HPHT diamond nanoparticles treated by three treating modes in Example 7.

FIG. 8 shows the selected area electron diffraction (SAED) patterns and the corresponding TEM images of (a) the HPHT diamond nanoparticles air oxidized at 600 ° C. for 2 hours in Example 6 and (b) the HPHT diamond nanoparticles air oxidized at 600 ° C. for 15 hours in Example 7.

FIG. 9 illustrates the evolution of the shape of a single diamond particle through air oxidation.

FIG. 10 shows the scattering spectrum of the diamond particle in the five phases of FIG. 9.

FIG. 11 shows the SHG spectrum (900 nm fs laser) of the raw and flower diamond particles.

FIG. 12 shows (a) SEM images of diamond particles in the same region before and after oxidation treatment at 650 ° C. for 1 hour, 2 hours, and 5 hours respectively; and (b) a large field of view SEM image of the treated sample.

FIG. 13 shows (a) BF TEM, (b) DF TEM, (c) High-angle annular dark-field (HAADF) STEM, and (d-f) HRTEM images of a cross-sectional raw “polyhedron” diamond particle.

FIG. 14 shows (a) BF TEM, (b) DF TEM, (c) High-angle annular dark-field (HAADF) STEM, and (d-f) HRTEM images of a cross-sectional “flower” diamond particle.

### DETAILED DESCRIPTION OF THE INVENTION

The present invention is further described in detail below in connection with specific embodiments, wherein the given embodiments are for illustrative purposes only and do not limit the scope of protection of the invention.

### Example 1

### Preparation of CVD Diamond Microparticles

(1) 0.1 g diamond nanoparticles (50 nm NDs, HPHT, PolyQolor, China) were mixed with 0.5 g sodium chloride (NaCl, 99.5%, Sigma-Aldrich), and they were heated at 500° C. for 1 hour in air. The resultant sample was dispersed in 100 mL deionized (DI) water and sonicated for 1 hour, and the NDs were then purified with DI water three times by centrifugation. The purified NDs were re-dispersed in DI water and sonicated for 2 hours to obtain well-dispersed NDs suspension (˜1 mg/mL) for the CVD growth of diamond.

(2) Before CVD growth, the silicon (Si) substrate was treated with hydrogen plasma for 10 minutes in the microwave-plasma assisted chemical vapor deposition (MPCVD) system (Seki 6350, power: 1300 W, chamber pressure: 35 torr, hydrogen (H₂) gas flow rate: 300 sccm). Then, 3 drops (50 μL) of the NDs suspension were spin-coated on the hydrogen plasma treated standard single-crystal Si (100) wafers (2 inches). The above spin coating process was repeated 5 times.

(3) The NDs spin-coated Si substrate was put in the MPCVD system for diamond growth with a gas mixture of H₂ (gas flow rate: 485 sccm) and methane (CH₄, gas flow rate: 15 sccm) under fixed power (3400 W), pressure (85 torr), and temperature (920° C.) conditions for 80 minutes.

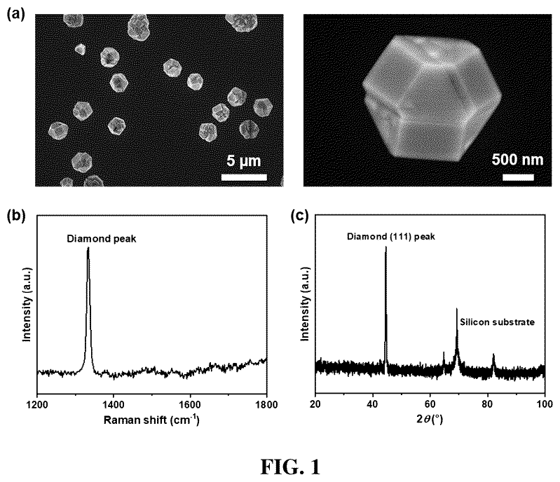

FIG. 1 shows (a) the scanning electron microscopy (SEM) images, (b) the Raman spectrum, and (c) the X-ray diffraction (XRD) result of the prepared diamond microparticles. As can be seen from the SEM images, the CVD-grown diamond microparticles have clear crystalline facets and a particle size in the range of 1 to 2 μm; the Raman spectrum displays a well-defined diamond Raman peak at 1333 cm⁻¹ without any obvious graphitic or amorphous contribution; and the X-ray diffraction (XRD) result also indicates the pure crystalline nature of the diamond microparticles, i.e., only the characteristic peaks of the diamond (111) plane (at 43.9°) and silicon substrate were found in the XRD spectrum. These results highlight the very high crystalline quality of the prepared CVD diamond microparticles.

### Example 2

Preparation of CVD Diamond Microparticles with a Flower like Shape

The as-grown CVD diamond microparticles in Example 1 were oxidized in the air at 600° C. for 30 hours to obtain the diamond microparticles with the flower like shape.

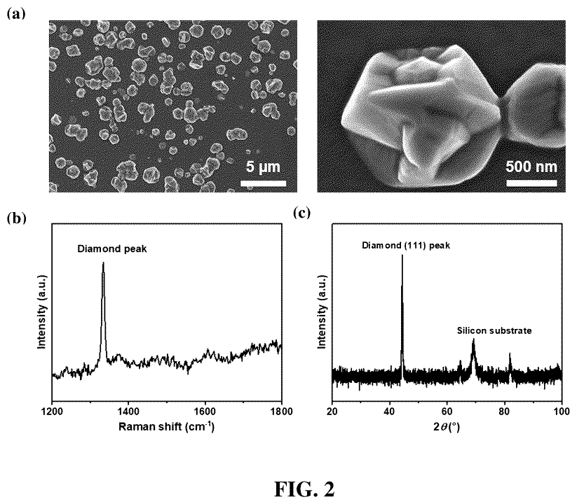

FIG. 2 shows (a) the SEM images, (b) the Raman spectrum, and (c) the XRD result of the flower shaped CVD diamond microparticles obtained by the air oxidation. As can be seen from the SEM images, clear “flower” shapes, i.e., the previously flat surfaces were carved with many concave surfaces to form the “flower” shape, were achieved in the CVD diamond microparticles; and the Raman and XRD spectrum clearly demonstrate the high crystalline quality of the “flower” shaped CVD diamond microparticles, without the presence of any apparent impurities' contribution.

### Example 3

Preparation of CVD Diamond Microparticles with “Pyramid” Patterns on the Surface

The as-grown CVD diamond microparticles in Example 1 were oxidized in the air at 600° C. for 15 hours, to obtain the diamond microparticles with “pyramid” patterns on the surface.

FIG. 3 shows the SEM images of the CVD diamond microparticles with “pyramid” patterns on the surface obtained by the air oxidation. FIG. 3 shows that there are multiple protrusions of “nano-pyramid” shape (a diameter of 50-100 nm) on the surfaces of the diamond microparticles.

### Example 4

Preparation of CVD Diamond Microparticles with “hollow” Structures

The as-grown CVD diamond microparticles in Example 1 were oxidized in the air at 650° C. for 20 hours, to obtain the diamond microparticles with the “hollow” structures.

FIG. 4 shows the SEM images of the CVD diamond microparticles with “hollow” structures obtained by the air oxidation. FIG. 4 shows that the diamond microparticles have clear “hollow” structures, i.e., some internal structures have been oxidized away.

### Example 5

Preparation of Densely Packed CVD Diamond Microparticles with “Hollow” Structures

The CVD diamond microparticles were grown by the method of Example 1, except for that the spin coating process in step (2) was repeated 15 times.

The prepared CVD diamond microparticles were oxidized in the air at 650° C. for 20 hours to obtain the densely packed diamond microparticles with “hollow” structures.

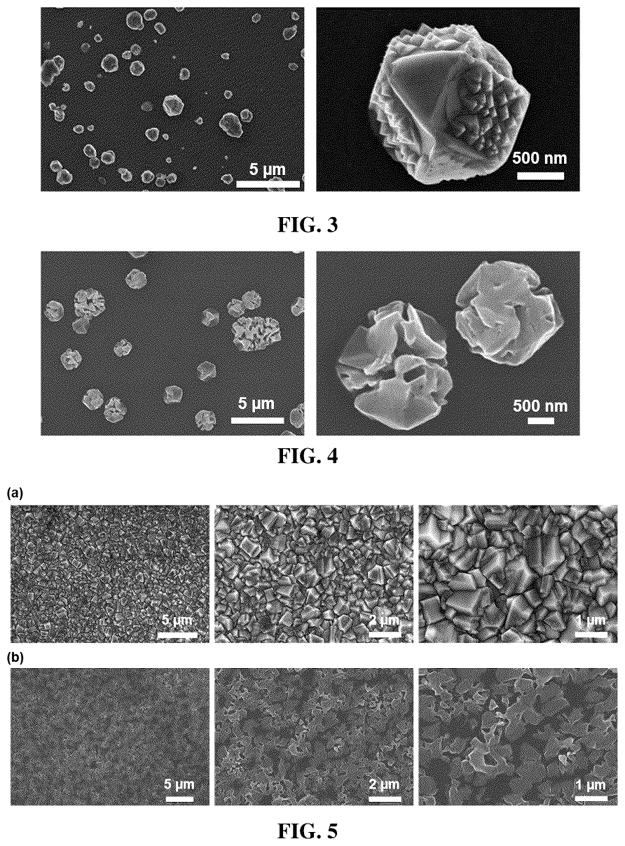

FIG. 5 shows (a) the SEM images of the CVD-grown diamond microparticles and (b) the densely packed CVD diamond microparticles with “hollow” structures after air oxidation prepared in this Example.

FIG. 5 shows that the densely packed diamond microparticles have clear “hollow” structures, i.e., some internal structures have been oxidized away.

### Example 6

Preparation of HPHT Diamond Nanoparticles with “Pyramids” Patterns on the Surface

Diamond nanoparticles with a mean particle size of 200 nm (HPHT, PolyQolor, China) were used as the starting material, and were subjected to air oxidation treatment by the following modes respectively:
(i) heating at 550° C. for 10 hours in the air;
(ii) heating at 550° C. for 20 hours in the air;
(iii) heating at 600° C. for 1 hour in the air; and
(iv) heating at 600° C. for 2 hours in the air.

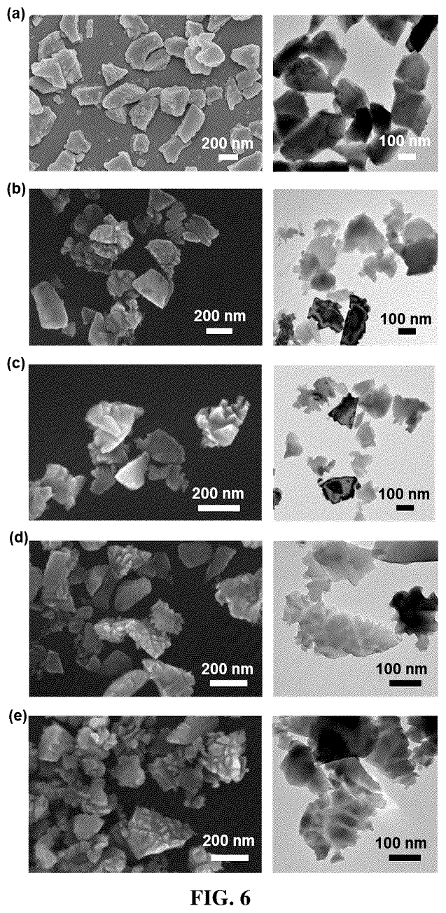

FIG. 6 shows the SEM and TEM images of the starting material HPHT diamond nanoparticles and the HPHT diamond nanoparticles treated by the four treating modes in this Example, wherein FIG. 6 in (a) is for the starting material HPHT diamond nanoparticles, and FIG. 6 in (b)-(e) are for the HPHT diamond nanoparticles prepared by the above treating modes (i)-(iv) in sequence. As shown in FIG. 6, the above four different treatments would all change the original diamond nanoparticles with a shard-like shape into diamond nanoparticles with “pyramid” (with a diameter of 5-20 nm) patterns on the surface.

### Example 7

Preparation of HPHT Diamond Nanoparticles with a “Boomerang” like Shape

Diamond nanoparticles with a mean particle size of 1 μm (HPHT, PolyQolor, China) were used as the starting material, and were subjected to air oxidation treatment by the following modes respectively:
(i) heating at 600° C. for 15 hours in the air;
(ii) heating at 600° C. for 20 hours in the air; and
(iii) heating at 600° C. for 25 hours in the air.

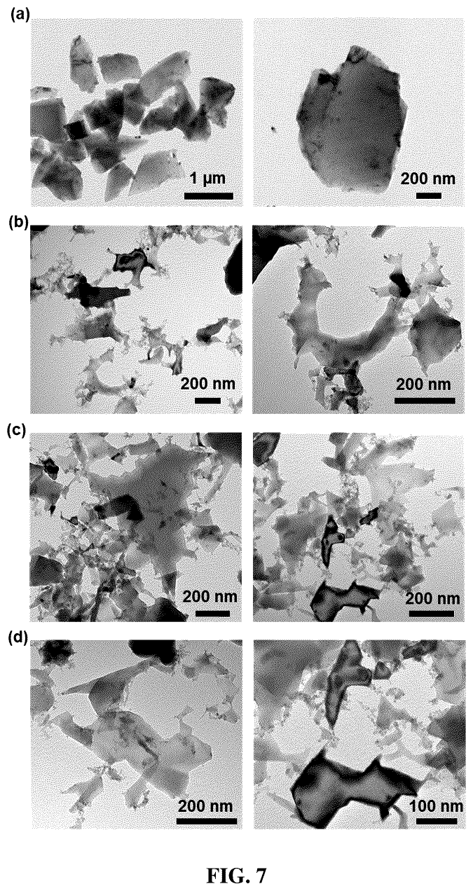

FIG. 7 shows the TEM images of the starting material HPHT diamond nanoparticles and the HPHT diamond nanoparticles treated by the three treating modes in this Example, wherein FIG. 7 in (a) is for the starting material HPHT diamond nanoparticles, and FIG. 7 in (b)-(d) are for the HPHT diamond nanoparticles prepared by the above treating modes (i)-(iii) in sequence. As shown in FIG. 7, the above three different treating modes would all change the original diamond microparticles with a shard-like shape into diamond nanoparticles with a “boomerang” like shape.

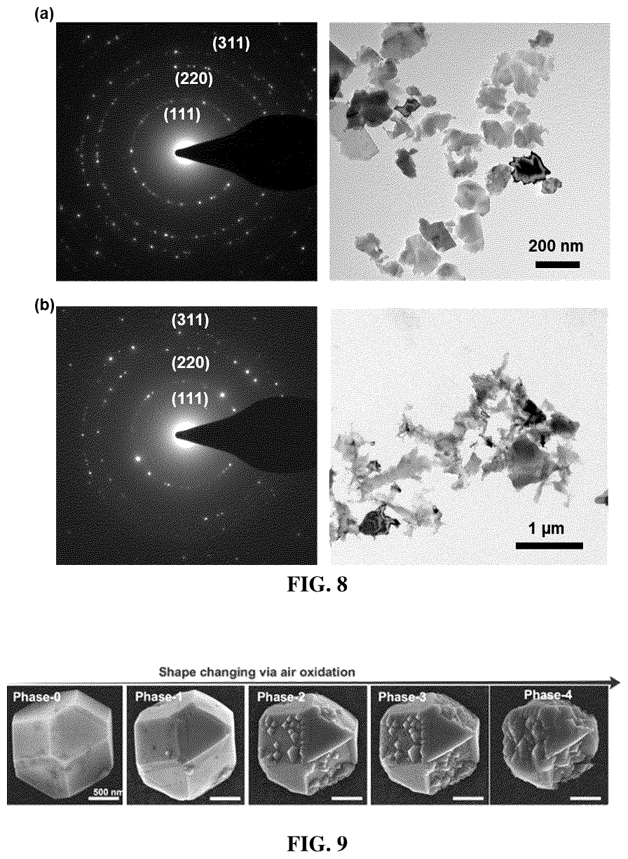

FIG. 8 shows the selected area electron diffraction (SAED) patterns and the corresponding TEM images of (a) the HPHT diamond nanoparticles air oxidized at 600° C. for 2 hours in Example 6 and (b) the HPHT diamond nanoparticles air oxidized at 600° C. for 15 hours in this Example. FIG. 8 clearly shows the crystal nature (the (111), (220), and (311) planes of the diamond are clearly shown in the diffraction patterns) is unchanged upon the air oxidation treatments, despite the significant morphology transformation.

### Example 8

### Influence of the Shape on Light Scattering

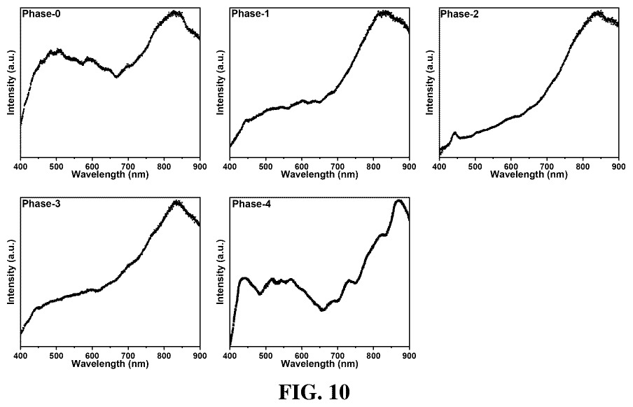

The light scattering spectra of the same diamond particles under different shapes were tested. FIG. 9. illustrates the evolution of a single diamond particle's shape through air oxidation, which occurs in five distinct phases with each phase being characterized by a different shape. The scattering spectrums of the diamond particle in the five phases of FIG. 9 are plotted in FIG. 10.

It was found that the corresponding scattering spectra exhibit significant differences, which reflects the correlation between shape and optical properties. This property has many potential applications, such as high-end information encryption, high-density optical data storage, anti-counterfeiting, and photonics.

### Example 9

### Influence of the Shape on Second-Harmonic Generation

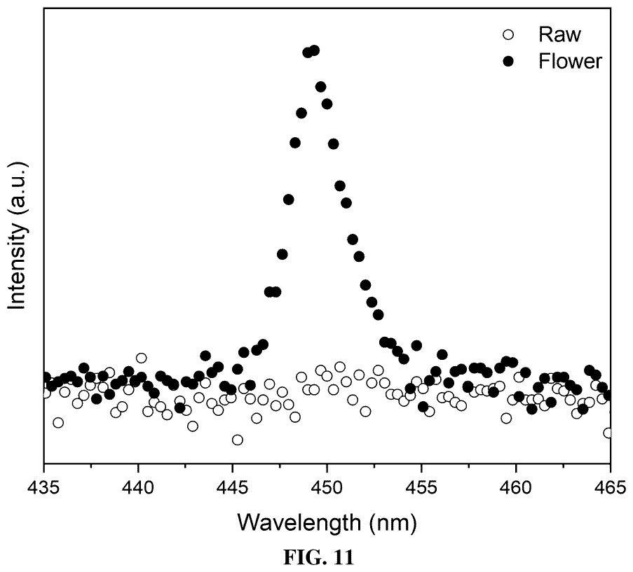

The second-harmonic generation (SHG) of diamond particles under different shapes prepared in the examples of the present invention (the raw and flower diamond particles) were tested, the results of which are shown in FIG. 11. It was found that the corresponding SHG spectra exhibit significant differences, which reflects the correlation between shape and optical properties. This property has many potential applications, such as high-end information encryption, high-density optical data storage, anti-counterfeiting, and photonics.

### Example 10

### High Yield of the Method of the Present Invention

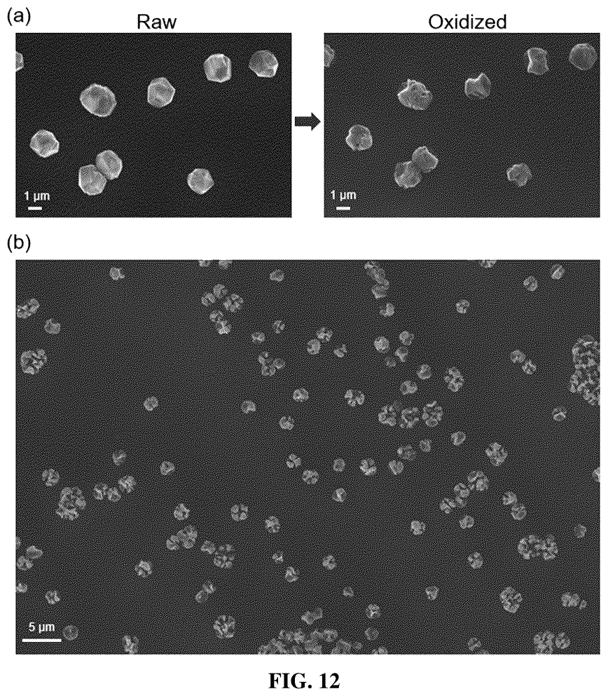

It was found that after the treatment of the method of the present invention, all the particles undergo shape changes. The results in FIG. 12 demonstrate this.

FIG. 12 in (a) shows the shape changes of diamond particles in the same region before and after oxidation treatment (at 650° C. for 1 hour, 2 hours, and 5 hours respectively). FIG. 12 in (b) displays a large field of view SEM image of the treated sample, indicating that all diamond particles within the field of view have transformed into a flower-like shape. Therefore, it can be confirmed that the method of the present invention has a high yield.

### Example 11

### Influence of Crystal Imperfections

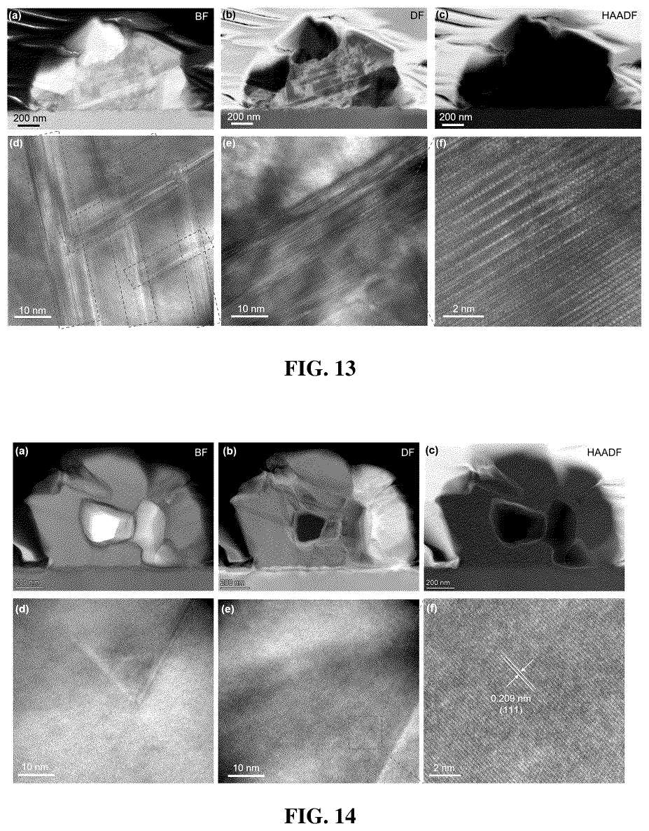

It has been discovered that the crystal imperfections in diamond particles may also affect the final shape. The detailed cross-sectional TEM/STEM characterizations of the raw “polyhedron” (FIG. 13) and “flower” (FIG. 14) diamond particles were performed.

From the bright field (BF)/dark field (DF) TEM and high-resolution (HR) TEM images of the raw “polyhedron” MD, it can be seen that it is polycrystalline particle composed of 3-4 crystals, containing many crystal imperfections, e.g., stacking faults and complex nanotwins (indicated by red dashed lines), which are common nanostructures in synthesized diamond. It is believed that those crystal defects would serve as the oxidation sites that have the tendency to react firstly and quickly at high temperatures, causing the particle to have a “hollowed/flowered” shape after oxidation. As evidenced by the BF/DF-TEM and HRTEM images of the “flower” MD (FIG. 14), there are some “holes” inside the particle, and there is also a significant decrease in crystal defects compared with the raw particle, indicating that the parts with poor crystallization quality have been oxidized away. Thus, it is believed that the level of crystal imperfections inside a diamond is another element that could control the shape of final diamonds.

The present invention provides a simple and efficient method for the arbitrary morphology modulation of both CVD-and HPHT-grown diamond micro-and nanoparticles by air oxidation treatment. For example, both CVD and HPHT diamond micro-and nanoparticles with “flower” shape, “hollow” structure, “pyramid” patterns on the surface, and “boomerang” shape are successfully achieved via fine-tuning of the air oxidation parameters (i.e., temperature and duration). These proposed methods represent a significant scientific breakthrough together with a high commercial value. The ability to produce diamond particles with desired shapes simply and cost-effectively will remove many obstacles to using diamonds for practical applications in nanophotonics, quantum computing, quantum optics, etc.

The above examples are only preferred examples of the present invention, and do not impose any limitation on the present invention. Without departing from the scope of the technical solutions of the present invention, any form of equivalent replacement or modification and other changes made by anyone skilled in the art to the technical solutions and technical contents of the present invention does not depart from the technical solutions of the present invention, and still belongs to the scope of protection of the present invention.

1. A scalable method for achieving shape control of diamond micro-nanoparticles, comprising air oxidizing diamond micro-nanoparticles grown by chemical vapor deposition and/or diamond micro-nanoparticles grown by high pressure and high temperature, wherein,
diamond micro-nanoparticles with a mean particle size of 10 nm to 500 nm are subjected to air oxidation under one of the following conditions:
5-25 hours of oxidation in the air at 530-570° C.;
10 min-10 hours of oxidation in the air at 580-620° C.; and
diamond micro-nanoparticles with a mean particle size of greater than 500 nm to 10 μm are subjected to air oxidation under one of the following conditions:
10-35 hours of oxidation in the air at 580-620° C.;
5-25 hours of oxidation in the air at 630-670° C.

2. The scalable method for achieving shape control of diamond micro-nanoparticles according to claim 1, wherein the preparation method for the diamond micro-nanoparticles grown by chemical vapor deposition comprises the following steps:
(1) mixing the diamond micro-nanoparticles grown by high pressure and high temperature with sodium chloride, and heating at 400-600° C. for 0.5-2 hours in the air; and dispersing the resultant product in deionized water and sonicating it, purifying it with deionized water one to five times by centrifugation, then re-dispersing it in deionized water and sonicating it for 0.5-3 hours to obtain a suspension of the diamond micro-nanoparticles; and
(2) spin-coating the suspension obtained in step (1) on a hydrogen plasma treated standard single-crystal Si substrate, and then putting the suspension spin-coated Si substrate in a microwave-plasma assisted chemical vapor deposition system, with a gas mixture of H₂ and methane for the growth of the diamond micro-nanoparticles.

3. The scalable method for achieving shape control of diamond micro-nanoparticles according to claim 2, wherein the diamond micro-nanoparticles grown by high pressure and high temperature in step (1) have a mean particle size of 50 nm to 200 nm.

4. The scalable method for achieving shape control of diamond micro-nanoparticles according to claim 2, wherein the diamond micro-nanoparticles grown in step (2) have a mean particle size of 1 to 2 μm.

5. A scalable method for preparing diamond microparticles with a flower like shape, comprising air oxidizing diamond micro-nanoparticles having a mean particle size of 1 to 2 μm grown by chemical vapor deposition in the air at 580-620° C. for 25-35 hours.

6. A scalable method for preparing diamond microparticles with pyramidpatterns on the surface, comprising air oxidizing diamond micro-nanoparticles having a mean particle size of 1 to 2 μm grown by chemical vapor deposition in the air at 580-620° C. for 10-20 hours.

7. A scalable method for preparing diamond microparticles with hollow structures, comprising air oxidizing diamond micro-nanoparticles having a mean particle size of 1 to 2 μm grown by chemical vapor deposition in the air at 630-670° C. for 15-25 hours.

8. A scalable method for preparing diamond nanoparticles with “pyramid” patterns on the surface, comprising air oxidizing diamond micro-nanoparticles having a mean particle size of 100 to 500 nm grown by high pressure and high temperature under one of the following conditions:
5-25 hours of oxidation in the air at 530-570° C.;
30 min-5 hours of oxidation in the air at 580-620° C.

9. A scalable method for preparing diamond microparticles with a boomerang like shape, comprising air oxidizing diamond micro-nanoparticles having a mean particle size of 500 nm to 2 μm grown by high pressure and high temperature in the air at 580-620° C. for 10-30 hours.
